(19) United States
(12) Patent Application Publication
(10) Pub. No.: US 2025/0391800 A1
(43) Pub. Date: Dec. 25, 2025

(54) ELECTRONIC DEVICE AND SOLDER REFLOW-LESS PROCESS

(71) Applicant: TEXAS INSTRUMENTS INCORPORATED, DALLAS, TX (US)

(72) Inventors: JOMARI AUSTRIA, MALABON CITY (PH); JEFFREY SOLAS, ILOILO CITY (PH)

(21) Appl. No.: 18/753,039

(22) Filed: Jun. 25, 2024

(51) Int. Cl. H01L 23/00; B23K 35/02; C25D 5/02; C25D 7/12; H01L 23/31

(52) U.S. Cl. CPC H01L 24/29; B23K 35/0222; H01L 23/3107; H01L 24/27; C25D 5/022; C25D 7/12; H01L 24/05; H01L 24/32; H01L 2224/05124; H01L 2224/05647; H01L 2224/27462; H01L 2224/29211; H01L 2224/29299; H01L 2224/32227

(57) ABSTRACT

An electronic device and method of making the electronic device are provided. The electronic device includes a die having an active side, where the active side includes interconnects. Conductive pads are disposed on a surface of the interconnects. A plated solder layer is formed on a surface of the conductive pads. The plated solder layer has a substantially smooth surface and includes a grain refiner additive and a leveler component.

### TECHNICAL FIELD

The present disclosure relates to an electronic device and more specifically, to an electronic device and a solder reflow-less process for integrated circuit packages.

### BACKGROUND

Some integrated circuit (IC) packages similar to that of a Wafer Level Chips Scale Package (WLCSP) are fabricated with electrically conductive pads connected to an active side of a die. Prior to attachment to an end user's electrical device, however, an oxide layer can form on the surface of the conductive pads. Oxidation can be caused by several sources, such as improper handling of the IC package, which can cause dirt or oil from the handler to form on the surface of the conductive pads or by humidity. The oxide layer has less electrical and thermal conductivity compared to the metal of the conductive pads. Thus, soldering the IC package to surface mount pads on the electrical device becomes very difficult. More specifically, the oxidation on the conductive pad reduces the contact rating of the solder contacts, which leads to faulty soldering. In other words, solder applied to the surface of the conductive pads won't properly adhere to the surface, therefore resulting in loose solder joints.

### SUMMARY

In a described example, a method includes forming conductive pads on an active surface of a substrate and forming a solder layer on the conductive pads, the solder layer having a substantially planar surface without undergoing a reflow process.

In another described example, a system includes an electronic device mounted to an electrical device, the electronic device includes a die having an active side, where the active side includes interconnects. Conductive pads are disposed on a surface of the interconnects. A solder layer is formed on a surface of the conductive pads. The solder layer has a substantially smooth surface and includes a grain refiner additive and a leveler component.

In still another described example, an electronic device includes a die having an active side, the active side having interconnects. Conductive pads are disposed on a surface of the interconnects. A plated solder layer is formed on a surface of the conductive pads. The plated solder layer has a substantially smooth surface and includes a grain refiner additive and a leveler component.

### BRIEF DESCRIPTION OF THE DRAWINGS

FIG. 1 is a cross-sectional view of an example electronic device.

FIGS. 2A-2C illustrate the electronic device of FIG. 1 being attached to an electrical device.

FIG. 3 is a block diagram flow chart illustrating a fabrication process for the electronic device of FIG. 1.

FIG. 4A is a top view of a substrate (e.g., wafer) that includes dies.

FIG. 4B illustrates a cross-sectional view of a singulated die from the wafer in FIG. 4A in the early stages of fabrication of the electronic device.

FIG. 4C illustrates a cross-sectional view of the electronic device of FIG. 4B after undergoing a first photoresist material layer patterning.

FIG. 4D illustrates a cross sectional view of the electronic device of FIG. 4C after undergoing a first plating process.

FIG. 4E illustrates a cross-sectional view of the electronic device of FIG. 4D after removal of the first photoresist material layer.

FIG. 4F illustrates a cross-sectional view of the electronic device of FIG. 4E after undergoing a second photoresist material layer patterning.

FIG. 4G illustrates a cross sectional view of the electronic device of FIG. 4F after undergoing a second plating process.

FIG. 4H illustrates a cross-sectional view of the electronic device of FIG. 4G after removal of the second photoresist material layer.

FIG. 4I illustrates a cross-sectional view of the electronic device of FIG. 4H after undergoing formation of a mold compound.

### DETAILED DESCRIPTION

Integrated circuit (IC) packages similar to that of a Wafer Level Chips Scale Package (WLCSP) are fabricated with electrically conductive pads connected to an active side of a die. These IC packages are shipped to an end user without solder or bump balls disposed on a surface of the conductive pads. Thus, when the IC packages are shipped to an end user, the end user applies solder to an electrical device (printed circuit board) and attaches to the IC package to the electrical device. Prior to attachment to the electrical device, however, an oxide layer can form on the surface of the conductive pads of the IC package. Oxidation can be caused by several sources, such as improper handling of the IC package, which can cause dirt or oil from the handler to form on the surface of the conductive pads or by humidity. The oxide layer has less electrical and thermal conductivity compared to the metal of the conductive pads. Thus, soldering the IC package to surface mount pads on the electrical device becomes very difficult. More specifically, the oxidation on the conductive pad reduces the contact rating of the solder contacts, which leads to faulty soldering. In other words, solder applied to the surface of the conductive pads won't properly adhere to the surface, therefore resulting in loose solder joints. The adhesion problem can create performance issues with the IC package, such as, compromised electrical conductivity.

In addition, in IC packages where solder is applied to the conductive pads during fabrication and prior to shipping the IC package to the end user, the solder must undergo a reflow process to smooth out a surface of the solder. Without undergoing the reflow process, the surface of the solder will be uneven and grainy. Thus, when the IC is attached to electrically conductive pads of the PCB, the grainy surface in the solder causes voids to be present between the solder and a surface of pads on the PCB. The voids in turn create adherence and contact problems between the IC and the electrical device. These problems can also result in faulty solder joints, which then compromises a performance of the assembled IC and PCB.

Disclosed herein is an electronic device (integrated circuit (IC)) and method of fabricating the electronic device that overcomes the aforementioned disadvantages. The method includes using a reflow-less solder to eliminate a reflow process during fabrication of the electronic device. More specifically, the solder layer is applied via an electroplating process and includes a grain refiner and a leveler, and is applied using a higher than normal current density, which results in a substantially planar surface for mounting to an end user's electrical device (e.g., printed circuit board (PCB)). In addition, the elimination of the reflow process limits intermetallic growth between the plated solder layer and conductive pads on the electronic device. An intermetallic compound (IMC) layer forms a mechanical joint between the plated solder layer and the conductive pads. Each time a reflow process is performed, a composition of the intermetallic compound layer changes and also becomes thicker. The change in composition and increase in thickness of the IMC layer compromises the electrical properties of the IMC layer and thus compromises performance of the electronic device. Thus, eliminating the reflow process during fabrication of the electronic device, mitigates the effects of a compromised IMC layer and also reduces fabrication costs. In addition, the substantially planar surface of the plated solder reduces the amount of voids present between the plated solder and the pads on the PCB.

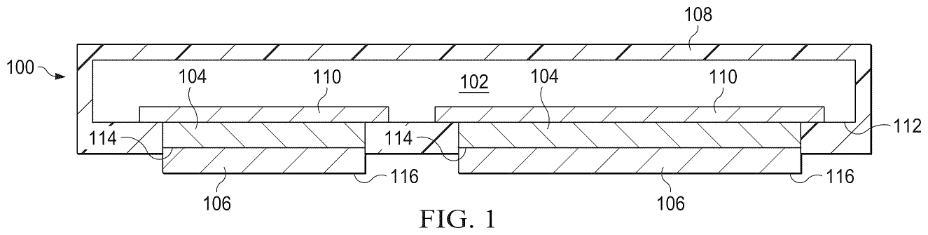

FIG. 1 is a cross sectional view of an example electronic device (e.g., integrated circuit (IC)) 100. The electronic device 100 is comprised of a substrate (e.g., die) 102, electrically conductive pads (e.g., copper pads) 104, a plated solder layer 106 disposed on the conductive pads 104, and an optional mold compound 108. The electronic device (e.g., integrated circuit (IC) package) may be similar to a Wafer Level Chips Scale Package (WLCSP) although, the electronic device 100 and method described herein may be applicable to other types of no-lead IC packages (e.g., QFN). Thus, the electronic device 100 illustrated in FIG. 1 is for illustrative purposes only and is not intended to limit the scope of the invention.

The die 102 includes one or more interconnects (e.g., aluminum pads) 110 disposed in or on an active side 112 of the die 102. In the example described herein and illustrated in the figures, the interconnects 110 are recessed in the active side 112 of the die 102 such that a surface of the interconnects 110 is substantially flush with a surface of the active side 112 of the die 102. The interconnects 110 provide a connection between the plated solder layer 106 and active circuits in the die 102. The conductive pads 104 attach to the active side of the die 102 via the interconnects 110. The plated solder layer 106 is disposed on a surface 114 of the conductive pads 104 via a plating process described further below. The plated solder layer 106 has a substantially planar surface 116 to facilitate attachment of the electronic device to an end user's electrical device (e.g., PCB). The mold compound 108 encapsulates the die 102 and covers all but one surface of the conductive pads 104, where the one surface not covered faces away from the die 102.

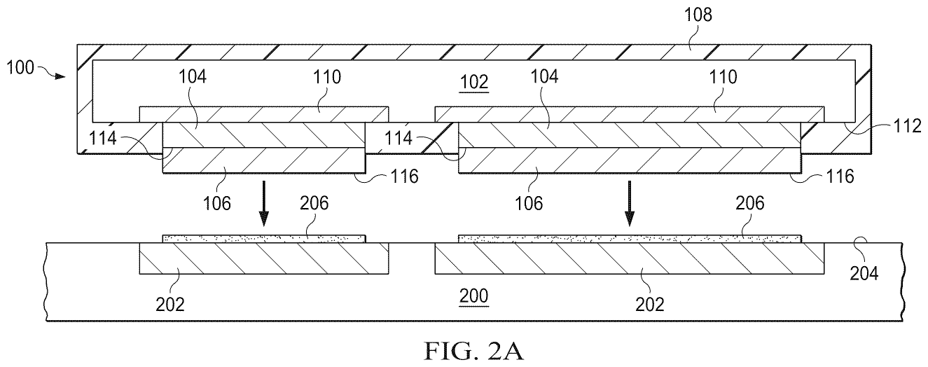

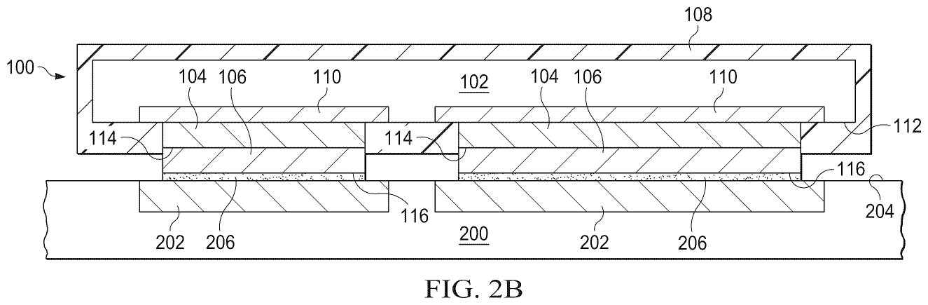

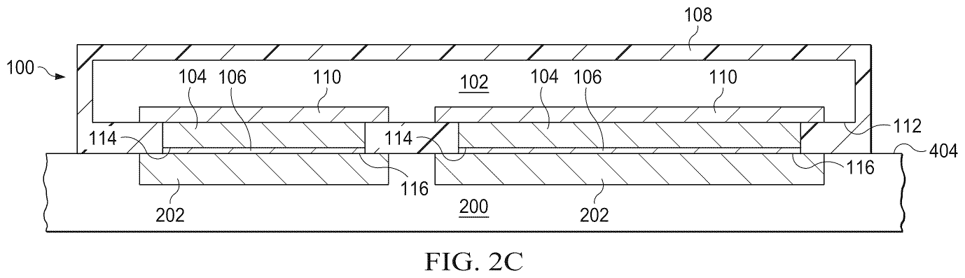

FIGS. 2A-2C are cross-sectional views of the electronic device 100 illustrated in FIG. 1 and an end user's electrical device 200. Referring to FIG. 2A, the electrical device 200 may be any type of electrical device that can accept and function with the electronic device 100, such as a printed circuit board (PCB). The electrical device 200 includes surface mount pads 202 disposed on or recessed into a surface 204 of the electrical device 200. A flux layer 206 is disposed on a surface of the surface mount pads 202 to facilitate adherence of the electronic device 100 to the electrical device 200.

FIGS. 2A-2C illustrate the placement of the electronic device 100 on the electrical device 200. As illustrated in FIG. 2B, the electronic device 100 is placed on the electrical device such that the conductive pads 104 of the electronic device 100 are aligned with the surface mount pads 202 of the electrical device 200. After placement of the electronic device 100 onto the electrical device 200, the plated solder layer 106 undergoes a reflow process to attach the electronic device 100 to the electrical device 200, as illustrated in FIG. 2C.

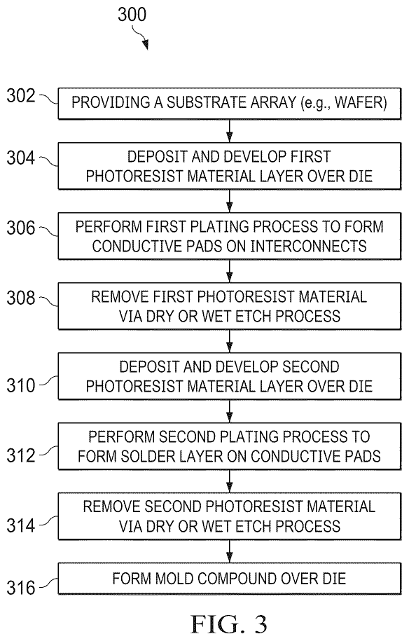

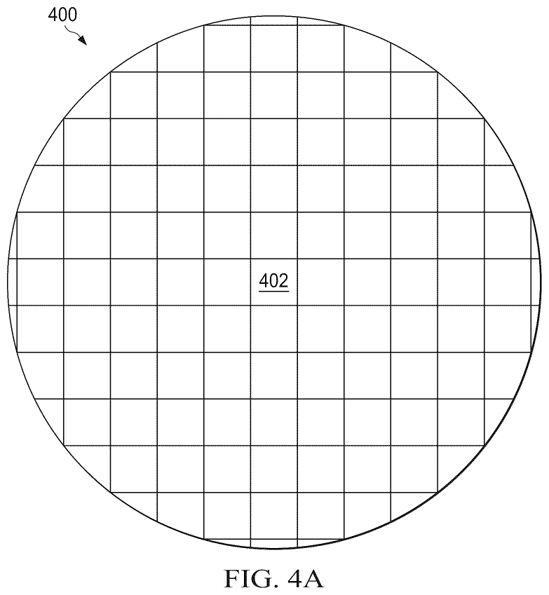

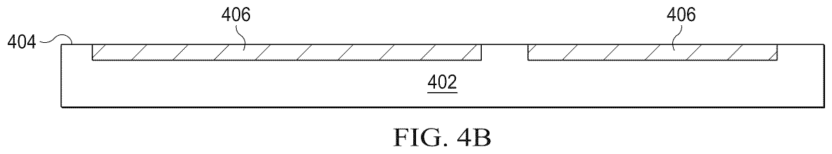

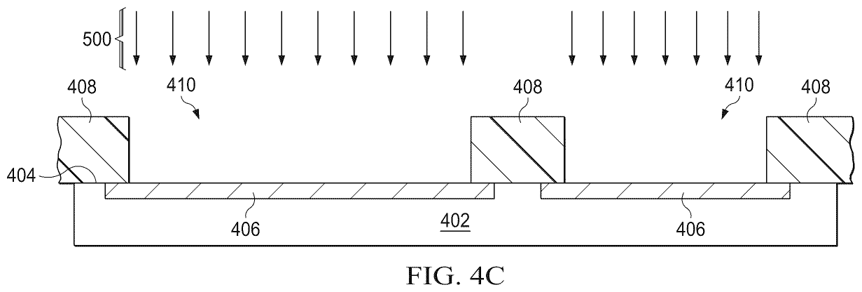

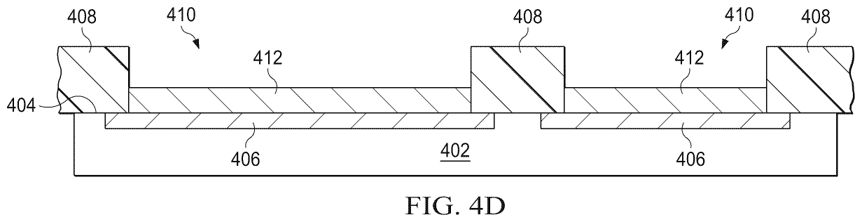

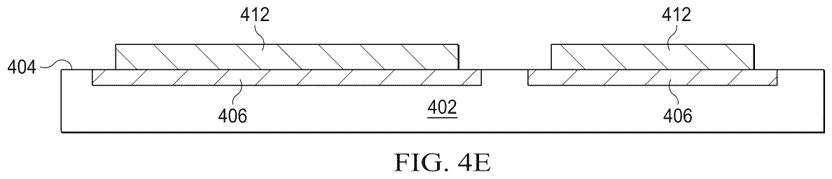

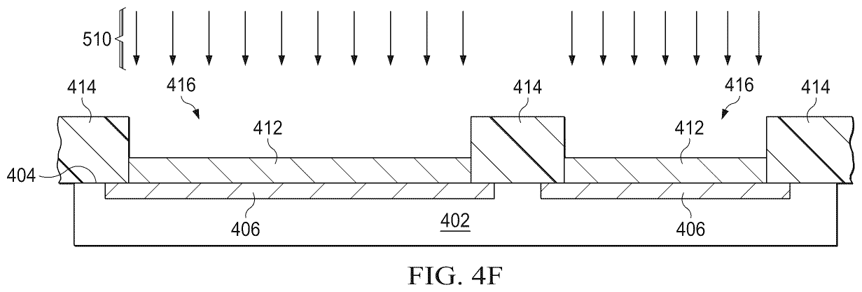

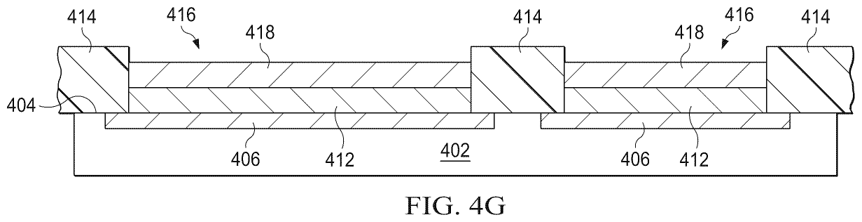

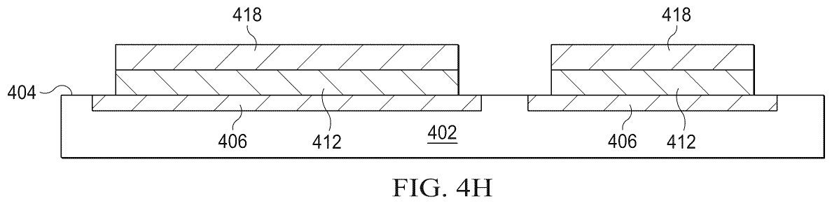

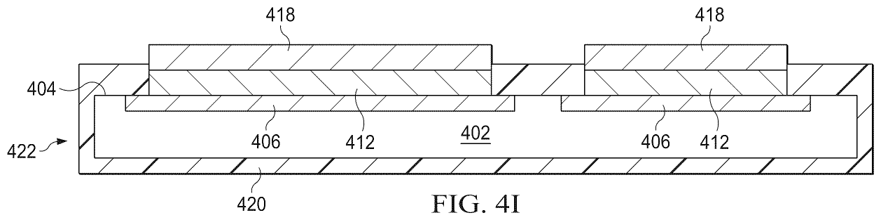

FIG. 3 is a block diagram flow chart explaining a fabrication process 300 and FIGS. 4A-4I illustrate a fabrication process associated with the formation of the electronic device 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 3 and 4A-4I is an example method illustrating the example configuration of FIG. 1, other methods and configurations are possible. It is understood that although the method illustrated in FIGS. 3 and 4A-4I depicts the fabrication process of a single electronic device, the process applies to an array of electronic devices. Thus, after fabrication of the array of electronic devices the array is singulated to separate each electronic device 100 from the array.

Referring to FIG. 3 and to FIGS. 4A-4I, the fabrication process of the electronic device 100 illustrated in FIG. 1 begins at 302 with a substrate (e.g., wafer) 400, as illustrated in FIG. 4A. Specifically, FIG. 4A is a schematic diagram of a wafer 400, in accordance with various examples. For example, the wafer 400 may be a silicon wafer. The wafer 400 comprises multiple dies 402. The manufacturing techniques described below may be performed on individual dies 402 (post-singulation), or the techniques may be more efficiently performed on a mass scale, e.g., simultaneously on multiple dies 402 of the wafer 400 (pre-singulation). For convenience and clarity, the remaining drawings show one die 402, with the understanding that the processes described herein as being performed on the die 402 may also be performed (e.g., sequentially performed, simultaneously performed) on the remaining dies 402 of the wafer 400.

FIG. 4B illustrates a cross sectional view of a single die 402 of the wafer 400 where the die 402 includes an active surface or side 404. Interconnects (e.g., aluminum interconnects) 406 are recessed into the active side 404 of the die 402, as illustrated in FIG. 4B. At 304, a first photoresist material layer 408 overlies the active side 404 of the die 402 and is patterned and developed to expose openings 410 in the first photoresist material layer 408 over the interconnects 406, resulting in the configuration of FIG. 4C. The first photoresist material layer 408 can have a thickness that varies in correspondence with the wavelength of radiation used to pattern the first photoresist material layer 408. The first photoresist material layer 408 may be formed over the active side 404 of the die 402 via spin-coating or spin casting deposition techniques, selectively irradiated (e.g., via deep ultraviolet (DUV) irradiation) and developed to form the openings 410.

At 306, the configuration in FIG. 4C undergoes a first plating (electroplating) process 500 to form conductive pads 412 in the openings 410 of the first photoresist material layer 408 and on a surface of the interconnects 406, resulting in the configuration of FIG. 4D. At 308, the first photoresist material layer 408 is removed via a dry or wet etch process, resulting in the configuration of FIG. 4E. At 310, a second photoresist material layer 414 overlies the active side 404 of the die 402 and is patterned and developed to expose openings 416 in the second photoresist material layer 414 over the conductive pads 412, resulting in the configuration of FIG. 4F. The second photoresist material layer 414 can have a thickness that varies in correspondence with the wavelength of radiation used to pattern the second photoresist material layer 414. The second photoresist material layer 414 may be formed over the active side 404 of the die 402 via spin-coating or spin casting deposition techniques, selectively irradiated (e.g., via deep ultraviolet (DUV) irradiation) and developed to form the openings 416.

At 312, the configuration in FIG. 4F undergoes a second plating (electroplating) process 510 to form a plated solder layer 418 in the openings 416 of the second photoresist material layer 414 and on a surface of the conductive pads 412, resulting in the configuration of FIG. 4G. The second plating process 510 is comprised of adding a grain refiner and a leveler component to an electrolyte solution comprising tin and at least one additional metal (e.g., lead, copper, silver, antimony). Both the grain refiner and the leveler make the plated solder layer more uniform, which in turn accounts for a substantially planar surface of the electroplated solder layer.

More specifically, the grain refiner promotes the formation of a fine-grain structure, which enhances the uniformity and smoothness of the plated surface. Moreover, it improves the metal's mechanical properties, such as increased hardness and strength, which can contribute to the durability of the plated item. In addition, a the presence of grain refiners affects the deposit in several ways: 1. Aesthetic Appeal: Smaller grains lead to a more lustrous and even appearance, which is often a key attribute for jewelry and decorative items. 2. Corrosion Resistance: Fine-grained coatings tend to have fewer defects, reducing the likelihood of corrosion initiation points. 3. Physical Properties: The smaller the grains, the better the hardness and wear resistance of the gold layer, making the plated object more resilient to physical stress and deformation. 4. Electrical Properties: A fine grain structure may influence the overall electrical performance by reducing the surface roughness, which could affect contact resistance. In addition, grain refiners help to further control the electroplating process. Grain refiners are attracted to the “high points” on the plated surface. If left untreated, the high points would tend to attract more metal deposition compared to lower points resulting in a rough surface. A grain refiner inhibits further deposition. As these points are replaced by other higher points the grain refiner will drift away and reposition itself.

Levelers are used to provide a smoother (substantially planar) plated surface. Specifically, levelers reduce a surface tension of the plating solution, which facilitates uniform deposition of metal across a substrate or other material. The leveling action works by slowing down the plating rate at the high current density regions (peaks) and accelerating it in recessed areas (valleys), leading to a more leveled, or even, metal deposition. The leveler may have one or more organic compounds acting as a leveler and are comprised of nitrogen-containing molecules (e.g., nitrogen-containing dyes, such as the Janus Green B (JGB), Alcian Blue (ABPV), Diazine Black (DB), etc.) or non-dye heterocyclic aromatic molecules (e.g., 2-amino-4-methylbenzothiazole (AMBT), 2-mercaptopyridine (2-MP), etc.). In addition, reducing an amount of the nitrogen containing compound may permit reduction of the overall total nitrogen-to-total carbon (TN/TOC) ratio. Lower TN/TOC ratios (e.g., 3% to 15%) results in less interference with a suppressor by the leveler.

The second plating process 510 is further comprised using a high current density (e.g., approximately 10 amperes per square decimeter (ASD)). The current density is an important parameter that is used to measure and control a thickness of the plated layer, i.e., solder, in the electroplating processes. It is the amount of current that passes through a given area and is usually expressed in amperes per square decimeter (ASD). The current density in an electroplating process is determined by the surface area of the workpiece and the total current used for the process. In order for the electroplating process to be successful, the current density must be carefully controlled. Variations in current density can have a significant impact on the quality of the electroplated coating. The higher the current density, the thicker the plated layer will be. Conversely, a lower current density can result in a thinner, weaker coating.

Current density also affects the rate at which the coating is deposited. A higher current density will speed up the rate of deposition, while a lower current density will slow it down. This can be beneficial in certain situations, such as when a thicker coating is needed in a short amount of time. A typical plating process uses a current density of approximately 4ASD. Thus, the second plating process 510 disclosed herein increases the current density from approximately 4ASD to approximately 10ASD to obtain a thicker, stronger plated layer.

Still referring to FIGS. 3 and 4A-4I, at 314, the second photoresist material layer 414 is removed via a dry or wet etch process, resulting in the configuration of FIG. 4H. At 316, an optional mold compound 420 is formed over the die 402. Specifically, the mold compound 420 encapsulates the die 402 and covers all but one surface of the conductive pads 412, where the one surface not covered faces away from the die 402, resulting in the electronic device 422 illustrated in FIG. 4I.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
forming conductive pads on an active surface of a substrate; and
forming a solder layer on the conductive pads, the solder layer having a substantially planar surface without undergoing a reflow process.

2. The method of claim 1, wherein forming a solder layer on the conductive pads includes performing an electroplating process to form a plated solder layer on the conductive pads.

3. The method of claim 2, wherein performing an electroplating process includes applying a current density of approximately 10 amperes per square decimeter.

4. The method of claim 3, wherein the plated solder layer includes a grain refiner additive and a leveler.

5. The method of claim 1, where prior to forming conductive pads on the active surface of the substrate, the method includes forming a first photoresist material layer over an active surface of a die.

6. The method of claim 5, wherein forming conductive pads on the active surface of the substrate includes performing a first plating process to form the conductive pads on interconnects recessed into the active surface of the substrate.

7. The method of claim 6, wherein prior to forming a solder layer of the conductive pads, the method includes forming a second photoresist material layer over the die.

8. The method of claim 7, wherein forming a solder layer on the conductive pads includes performing a second plating process to form a plated solder layer on the conductive pads.

9. The method of claim 8, wherein performing a second plating process to form a plated solder layer on the conductive pads includes applying a current density of approximately 10 amperes per square decimeter.

10. The method of claim 9 further comprising forming a mold compound over the die, the mold compound encapsulating the die and covering all but one surface of the conductive pads, where the one surface not covered faces away from the die.

11. A system comprising:
an electronic device mounted to an electrical device, the electronic device comprising:
a die having an active side, the active side having interconnects;
conductive pads disposed on a surface of the interconnects; and
a solder layer formed on a surface of the conductive pads, the solder layer having a substantially smooth surface, the solder layer comprising a grain refiner additive and a leveler component.

12. The system of claim 11, wherein the solder layer is formed via an electroplating process to form a plated solder layer, the plated solder layer including a substantially planar surface without undergoing a reflow process.

13. The system of claim 12, wherein the plated solder layer includes a grain refiner additive and a leveler.

14. The system of claim 13, wherein the electrical device is a printed circuit board, and wherein the plated solder layer of the electronic device attaches to surface mount pads on the printed circuit board.

15. The system of claim 11, wherein the interconnects are recessed in the active side of the die such that a surface of the interconnects is substantially flush with a surface of the active side of the die.

16. The system of claim 11, further comprising a mold compound formed over and encapsulating the die, the mold compound covering all but one surface of the conductive pads, where the one surface not covered faces away from the die.

17. An electronic device comprising:
a die having an active side, the active side having interconnects;
conductive pads disposed on a surface of the interconnects; and
a plated solder layer formed on a surface of the conductive pads, the plated solder layer having a substantially smooth surface, the plated solder layer comprising a grain refiner additive and a leveler component.

18. The electronic device of claim 17, wherein the plated solder layer is formed via an electroplating process and includes a substantially planar surface without undergoing a reflow process.

19. The electronic device of claim 17, wherein the interconnects are recessed in the active side of the die such that a surface of the interconnects is substantially flush with a surface of the active side of the die.

20. The electronic device of claim 17, further comprising a mold compound formed over and encapsulating the die, the mold compound covering all but one surface of the conductive pads, where the one surface not covered faces away from the die.
